(19) United States
(12) Patent Application Publication
(10) Pub. No.: US 2026/0050025 A1
(43) Pub. Date: Feb. 19, 2026

(54) APPARATUS AND METHOD FOR TESTING POWER SEMICONDUCTOR CHIP

(71) Applicants: HYUNDAI MOTOR COMPANY, SEOUL (KR); KIA CORPORATION, SEOUL (KR)

(72) Inventor: Tae Woo Kwang, Hwaseong-si (KR)

(73) Assignees: HYUNDAI MOTOR COMPANY, SEOUL (KR); KIA CORPORATION, SEOUL (KR)

(21) Appl. No.: 19/045,879

(22) Filed: Feb. 5, 2025

(30) Foreign Application Priority Data
Aug. 14, 2024 (KR) 10-2024-0108815

(51) Int. Cl. G01R 31/26

(52) U.S. Cl. CPC G01R 31/2601

(57) ABSTRACT

An apparatus for testing a power semiconductor chip includes a chuck having a surface configured so that a power semiconductor chip is positioned on the surface of the chuck, a direct connection portion including a plurality of wire probes directly contacting one surface of the power semiconductor chip, and an indirect connection portion forming an electrical connection path to the other surface of the power semiconductor chip through the chuck, wherein each of the plurality of wire probes is configured to be bendable by pressure applied to both ends of each of the plurality of wire probes.

### CROSS REFERENCE TO RELATED APPLICATIONS

This application claims benefit of priority to Korean Patent Application No. 10-2024-0108815 filed on Aug. 14, 2024 in the Korean Intellectual Property Office, the disclosure of which is incorporated herein by reference in its entirety.

### BACKGROUND

1. FIELD The present disclosure relates to an apparatus and method for testing a power semiconductor chip.

### 2. DESCRIPTION OF RELATED ART

A power conversion device (e.g., an inverter) of an eco-friendly vehicle (e.g., an electric vehicle (EV), a hybrid vehicle (HEV), a plug-in hybrid vehicle (HEV), a fuel cell electric vehicle (FCEV)) receives DC current from a high-voltage battery, converts it into AC current, supplies it to a motor, and controls torque and rotation speed of the motor by adjusting the magnitude and phase of the AC current. A power module of the power conversion device may include one or more power semiconductor chips that convert DC current received from a high-voltage battery into AC current.

A failure of the power semiconductor chip may lead to a decrease in the safety of at least one of the power module, the power conversion device (e.g., the inverter), and the eco-friendly vehicle and may incur failure costs (e.g., disposal costs).

### SUMMARY

An aspect of the present disclosure is to test a power semiconductor chip, thereby preventing deterioration of safety of at least one of the power module, inverter, and eco-friendly vehicle due to a defective power semiconductor chip and also reducing the failure costs (e.g., disposal costs).

In order to test a power semiconductor chip, it is necessary to form a path through which a large current flows in the power semiconductor chip. However, the process for forming a path through which a large current flows (e.g., physical contact with the power semiconductor chip) may damage the power semiconductor chip.

Therefore, the apparatus and method for testing a power semiconductor chip according to an embodiment of the present disclosure may prevent damage to a power semiconductor chip when forming a path through which a large current flows for testing the power semiconductor chip.

According to an aspect of the present disclosure, an apparatus for testing a power semiconductor chip includes a chuck having one surface configured so that a power semiconductor chip is disposed thereon, a direct connection portion including a plurality of wire probes directly contacting one surface of the power semiconductor chip, and an indirect connection portion forming an electrical connection path to the other surface of the power semiconductor chip through the chuck. Each of the plurality of wire probes is configured to be bendable by pressure applied to both ends of each of the plurality of wire probes.

The indirect connection portion may be configured to directly contact a region of one surface of the chuck not overlapping the power semiconductor chip.

The indirect connection portion may include a leaf spring.

The apparatus for testing a power semiconductor chip may further include a measuring device outputting current to the indirect connection portion and measuring an electrical parameter through the direct connection portion.

The chuck may have a vacuum suction hole sucking the power semiconductor chip.

Each of the plurality of wire probes may include a wire body and a contact portion, and the contact portion may be connected between the wire body and the power semiconductor chip and have a diameter shorter than a diameter of the wire body.

A total current capacity of the plurality of wire probes may exceed 100 A.

A current capacity of each of the plurality of wire probes may be less than 10 A.

The direct connection portion may further include a connecting member having a through-hole, through which the plurality of wire probes pass, and being fixed to the plurality of wire probes through the through-hole.

The connecting member may include a lower fixing member having a through-hole, through which the plurality of wire probes pass, and being fixed to a lower portion of the plurality of wire probes through the through-hole of the lower fixing member, an upper fixing member having a through-hole, through which the plurality of wire probes pass and being fixed to an upper portion of the plurality of wire probes through the through-hole of the upper fixing member, and a support member supporting between the lower fixing member and the upper fixing member.

The power semiconductor chip may be a single power semiconductor chip, one of a plurality of power semiconductor chips divided from a wafer.

A total arrangement range of the plurality of wire probes may be less than or equal to an area of one surface of the single power semiconductor chip.

According to another aspect of the present disclosure, a method for testing a power semiconductor chip includes placing a power semiconductor chip on a vacuum suction hole of one surface of a chuck, bringing a plurality of wire probes electrically connected to a measuring device into contact with the power semiconductor chip and connecting an indirect connection portion electrically connected to the measuring device to the chuck to form a current path; and outputting by the measuring device, current to the indirect connection portion and measuring an electrical parameter through the plurality of wire probes.

The indirect connection portion may include a leaf spring.

By the operation of forming the current path, the indirect connection portion may be disposed in a region of one surface of the chuck not overlapping the power semiconductor chip.

By the operation of measuring, a total current flowing through the plurality of wire probes may exceed 100 A, and current flowing through each of the plurality of wire probes may be less than 10 A.

The power semiconductor chip disposed on the vacuum suction hole of the chuck by the placing operation may be a single power semiconductor chip, one of a plurality of power semiconductor chips divided from a wafer, and a total arrangement range of the plurality of wire probes directly contacting the single power semiconductor chip by the forming operation may be less than or equal to an area of one surface of the single power semiconductor chip.

### BRIEF DESCRIPTION OF THE FIGURES

The and other aspects, features, and advantages of the present disclosure will be more clearly understood from the following detailed description, taken in conjunction with the accompanying drawings, in which:

FIG. 1 is a view illustrating an apparatus for testing a power semiconductor chip according to an embodiment of the present disclosure;

FIGS. 2A, 2B, and FIG. 2C are views illustrating operations for testing a power semiconductor chip by an apparatus and method for testing a power semiconductor chip according to an embodiment of the present disclosure;

FIG. 3 is a perspective view illustrating a direct connection portion and an indirect connection portion of an apparatus and method for testing a power semiconductor chip according to an embodiment of the present disclosure;

FIG. 4 is a side view illustrating bending of a plurality of wire probes of an apparatus and method for testing a power semiconductor chip according to an embodiment of the present disclosure; and

FIG. 5 is a flowchart illustrating a method for testing a power semiconductor chip according to an embodiment of the present disclosure.

### DETAILED DESCRIPTION

While the present disclosure may be modified in various ways and take on various alternative forms, specific embodiments thereof are illustrated in the drawings and described in detail below. However, it should be understood that there is no intent to limit the present disclosure to the particular forms disclosed, but on the contrary, the present disclosure covers all modifications, equivalents, and alternatives falling within the spirit and scope of the present disclosure.

It will be understood that, although the terms “first,” “second,” etc. may be used herein to describe various elements, these elements should not be limited by these terms. These terms are only used to distinguish one element from another. For example, a first element could be termed a second element, and a second element could similarly be termed a first element without departing from the scope of the present disclosure. As used herein, the term “and/or” includes any and all combinations of one or more of the associated listed items.

The terms used herein to describe embodiments of the present disclosure are not intended to limit the scope of the present disclosure. The articles “a,” and “an” are singular in that they have a single referent, however the use of the singular form in the present document should not preclude the presence of more than one referent. In other words, elements of the present disclosure referred to in the singular may number one or more, unless the context clearly indicates otherwise. It will be further understood that the terms “comprise,” “comprising,” “include,” and/or “including,” when used herein, specify the presence of stated features, numbers, steps, operations, elements, and/or components but do not preclude the presence or addition of one or more other features, numbers, steps, operations, elements, components, and/or groups thereof.

Unless defined in a different way, all the terms used herein including technical and scientific terms have the same meanings as understood by those skilled in the art to which the present disclosure pertains. Such terms as defined in generally used dictionaries should be construed to have the same meanings as those of the contexts of the related art, and unless clearly defined in the application, they should not be construed to have ideally or excessively formal meanings.

In this specification, vehicles (including electric vehicles) refer to a variety of vehicles that move transported objects, such as people, animals, or goods, from a starting point to a destination. These vehicles are not limited to vehicles that run on roads or tracks.

Hereinafter, embodiments of the present disclosure will be described with reference to the accompanying drawings.

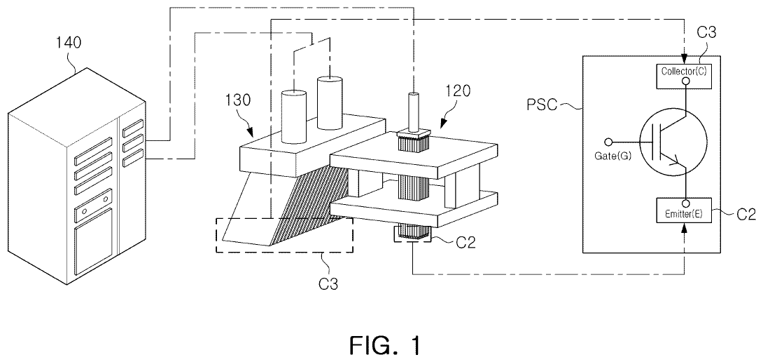

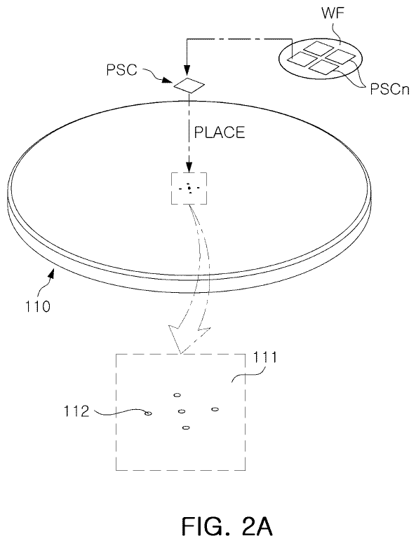

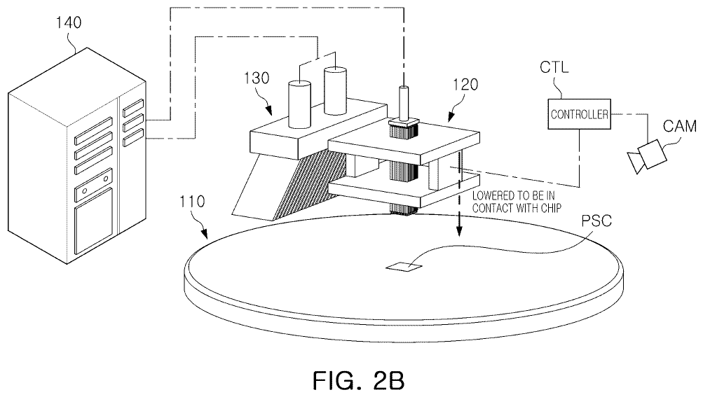

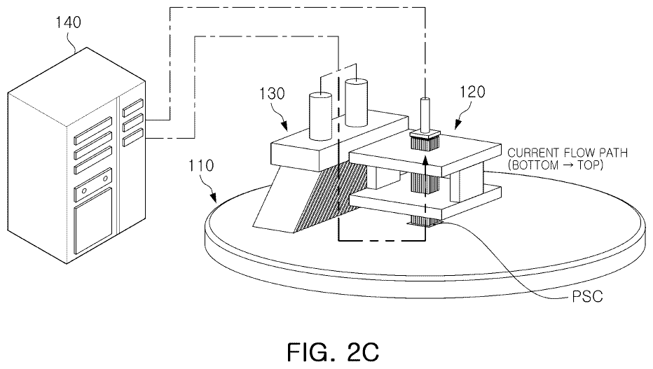

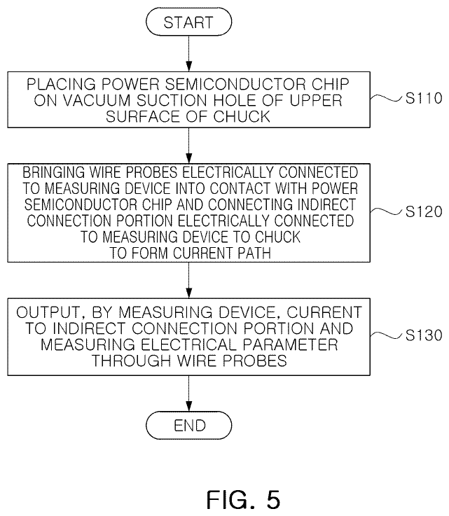

FIG. 1 is a view illustrating an apparatus for testing a power semiconductor chip according to an embodiment of the present disclosure, FIG. 2A to FIG. 2C are views illustrating operations for testing a power semiconductor chip by an apparatus and method for testing a power semiconductor chip according to an embodiment of the present disclosure, and FIG. 5 is a flowchart illustrating a method for testing a power semiconductor chip according to an embodiment of the present disclosure.

Referring to FIGS. 1 to 2C, an apparatus for testing a power semiconductor chip according to an embodiment of the present disclosure may include a chuck 110, a direct connection portion 120, and an indirect connection portion 130 and may further include a measuring device 140 and may test a power semiconductor chip (PSC).

The power semiconductor chip PSC may include one or more power semiconductor devices having a high power capacity, such as an insulated gate bipolar transistor (IGBT) or a thyristor, and the power semiconductor device may include a gate G, an emitter E, and a collector C. For example, one surface of the power semiconductor chip PSC may include an electrode region C2 to which the emitter E of the power semiconductor device is connected, and the other surface of the power semiconductor chip PSC may include an electrode region C3 to which the collector C of the power semiconductor device is connected. This structure may be defined as a longitudinal power semiconductor device structure. The one surface and the other surface may be an upper surface and a lower surface, respectively, but are not limited thereto.

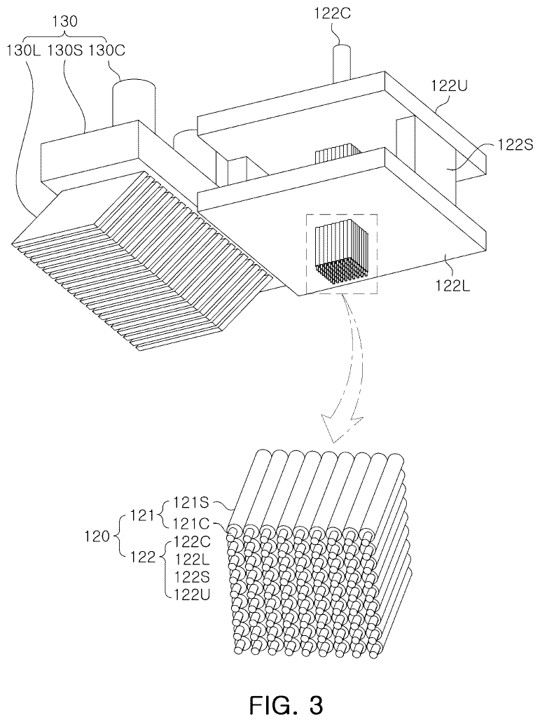

The measuring device 140 may output a current to the indirect connection portion 130 by applying a voltage signal (e.g., a direct current (DC) voltage or ab alternating current (AC) voltage) between the electrode region C3 and the electrode region C2 of the power semiconductor chip PSC, may form a current flowing from the electrode region C3 to the electrode region C2, and may test an electrical parameter (e.g., equivalent impedance, withstand voltage characteristics, current capacity, etc. of the power semiconductor chip PSC) based on the current through a plurality of wire probes (121 of FIG. 3) of the direct connection portion 120.

For example, the measuring device 140 may compare the electrical parameter with a reference value and generate quality information (e.g., information on whether it is defective) of the power semiconductor chip PSC based on a comparison result. The power semiconductor chip PSC selectively disposed in a power module according to the quality information. For example, the power module may include one or more power semiconductor chips (PSCs), may be electrically connected between a motor and a battery for driving an eco-friendly vehicle such as an electric vehicle, and may be implemented as an inverter converting DC voltage of the battery into an AC voltage.

The apparatus and method for testing a power semiconductor chip according to an embodiment of the present disclosure may test the power semiconductor chip PSC, thereby preventing the safety of at least one of the power module, the inverter, and an eco-friendly vehicle from being deteriorated by a defective power semiconductor chip and reducing failure costs (e.g., disposal costs). In addition, the apparatus and method for testing a power semiconductor chip may also prevent additional damage to the power semiconductor chip PSC during the process of testing the power semiconductor chip PSC.

Referring to FIGS. 1 and 2A, the chuck 110 may have one surface 111 configured so that the power semiconductor chip PSC is disposed thereon. For example, the chuck 110 may be implemented as a chuck table or a chuck stage, and an area of one surface 111 of the chuck 110 may be larger than that of a single power semiconductor chip PSC. The chuck 110 may be smaller than a chuck for a wafer, but is not limited thereto. For example, one surface 111 of the chuck 110 may have one or more vacuum suction holes 112. Accordingly, the power semiconductor chip PSC may be fixed on the vacuum suction holes 112. A diameter of the vacuum suction holes 112 may be shorter than a length of the power semiconductor chip PSC in one direction, and the arrangement range of a plurality of vacuum suction holes 112 may be less than the area of the power semiconductor chip PSC, but is not limited thereto. The chuck 110 may have a cylindrical shape, but since the chuck 110 may not be for a wafer (WF of FIG. 2A), the shape of the chuck 110 is not limited to the cylindrical shape.

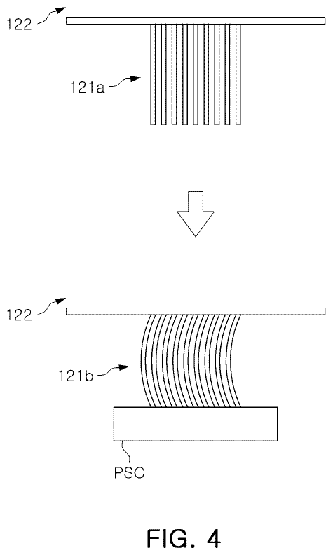

Referring to FIG. 1 and FIG. 4, the direct connection portion 120 may include a plurality of wire probes 121 directly contacting one surface (e.g., the electrode region C2) of the power semiconductor chip PSC. Each of the plurality of wire probes 121a may be configured to be bent by pressure applied to both ends of each of a plurality of wire probes 121b. As the plurality of wire probes 121a are bent to the plurality of wire probes 121b, the impact due to direct contact between the plurality of wire probes 121 and one surface (e.g., the electrode region C2) of the power semiconductor chip PSC may be alleviated. Therefore, damage to the power semiconductor chip PSC may be prevented.

For example, each of the plurality of wire probes 121 may have a thin and long shape to have a stroke section and may include a metal material (e.g., copper, aluminum, gold, or silver) which is flexible and has high conductivity, but is not limited thereto. For example, each of the plurality of wire probes 121 may be more easily bent than a pogo pin and may have a more simplified structure than the pogo pin. Since each of the plurality of wire probes 121 may have a simplified structure, the aspect ratio of each of the plurality of wire probes 121 may be higher than the aspect ratio of the pogo pin, and the plurality of wire probes 121 may be arranged more densely (e.g., tens to hundreds of wire probes may be arranged) than the pogo pin.

According to the high aspect ratio of each of the plurality of wire probes 121, even if the current capacity of each of the plurality of wire probes 121 is low, the total current capacity of the plurality of wire probes 121 may efficiently increase. For example, the total current capacity of the plurality of wire probes 121 may exceed 100 A, and the current capacity of each of the plurality of wire probes 121 may be less than 10 A, but is not limited thereto. The current capacity of the plurality of wire probes 121 may be defined as a current size at which a saturation phenomenon (and/or a phenomenon in which the wire probes are damaged by the current) occurs in the increase of the current according to the increase of the voltage, but is not limited thereto.

Referring to FIG. 1 and FIG. 2C, the indirect connection portion 130 may form an electrical connection path to the other surface (e.g., the electrode region C3) of the power semiconductor chip PSC through the conductive chuck 110. Accordingly, since the indirect connection portion 130 may not contact the power semiconductor chip PSC, damage to the power semiconductor chip PSC may be prevented. For example, the chuck 110 may be conductive by at least a portion of the chuck 110 being formed of a highly conductive metal material or by wiring or circuits being built into the chuck 110.

Referring to FIG. 2A and FIG. 5, a method for testing a power semiconductor chip according to an embodiment of the present disclosure may include operation (S110) of placing a power semiconductor chip PSC on a vacuum suction hole 112 of one surface 111 of the chuck 110. For example, the placing operation (S110) may be implemented by a pick-and-place device picking up the power semiconductor chip PSC and placing it on the chuck 110. For example, the power semiconductor chip PSC may be a single power semiconductor chip, one of a plurality of power semiconductor chips divided from a wafer WF. For example, the total arrangement range of the plurality of wire probes (121 of FIG. 3) may be less than or equal to the area of one surface of the single power semiconductor chip.

Referring to FIGS. 2B, 2C, and 5, the method for testing a power semiconductor chip may include operation (S120) of bringing a plurality of wire probes (121 of FIG. 3) electrically connected to the measuring device 140 into contact with the power semiconductor chip PSC and connecting the indirect connection portion 130 electrically connected to the measuring device 140 to the chuck 110 to form a current path and may further include operation (S130) of the measuring device 140 outputting current to the indirect connection portion 130 and measuring an electrical parameter through the plurality of wire probes (121 of FIG. 3).

By the operation (S120) of forming the current path, the indirect connection portion 130 may be disposed in a region (e.g., a region outside the vacuum suction hole 112) of one surface of the chuck 110 not overlapping the power semiconductor chip PSC. The indirect connection portion 130 may be configured to directly contact a region of one surface of the chuck 110 not overlapping the power semiconductor chip PSC.

Since the area of one surface of the chuck 110 is not required to be large, a region of one surface of the chuck 110 not overlapping the power semiconductor chip PSC may be easily secured. Accordingly, a connection position accuracy when the indirect connection portion 130 is connected to a specific position on one surface of the chuck 110 may be rarely required, and connection failure or micro-electrical short-circuit when the indirect connection portion 130 is connected to the chuck 110 may be prevented. Since the connection failure or micro-electrical short-circuit may be a factor lowering the evaluation accuracy of the power semiconductor chip PSC, preventing the occurrence of the connection failure or micro-electrical short-circuit may mean improving the evaluation accuracy of the power semiconductor chip PSC. That is, the apparatus and method for testing a power semiconductor chip according to an embodiment of the present disclosure may improve the connection stability between the indirect connection portion 130 and the chuck 110, and thus may improve the evaluation accuracy of the power semiconductor chip PSC.

In addition, the chuck 110 may form an electrical connection path between the indirect connection portion 130 and the power semiconductor chip PSC, and since both the indirect connection portion 130 and the power semiconductor chip PSC are connected on one surface of the chuck 110, the electrical connection path may be formed efficiently (e.g., formed to be short). Therefore, the energy loss (e.g., loss due to equivalent series resistance or loss due to energy leaking out) of the current flowing through the electrical connection path may be reduced.

Meanwhile, referring to FIG. 2B, the apparatus and method for testing a power semiconductor chip according to an embodiment of the present disclosure may further include a controller CTL moving the direct connection portion 120 and/or the indirect connection portion 130 to a specific horizontal position and lowering it toward the chuck 110 and may further include a camera CAM imaging at least one of the chuck 110, the direct connection portion 120, and the indirect connection portion 130 while the controller CTL controls the movement of the direct connection portion 120 and/or the indirect connection portion 130. The camera CAM may transmit a captured image to the controller CTL, and the controller CTL may generate position information of the direct connection portion 120 and/or the indirect connection portion 130 from the captured image, and control a movement distance (and/or applied force) of the direct connection portion 120 and/or the indirect connection portion 130 based on the position information. For example, the controller CTL may be implemented as a computing system (including a processor, a memory, an input/output device, and a communication device).

FIG. 3 is a perspective view illustrating a direct connection portion and an indirect connection portion of an apparatus and method for testing a power semiconductor chip according to an embodiment of the present disclosure.

Referring to FIG. 3, the indirect connection portion 130 may include a jig 130C, a support portion 130S, and a leaf spring 130L. The leaf spring 130L may alleviate impact when there is direct contact between the indirect connection portion 130 and the chuck (110 of FIG. 2C), and thus, contact stability (e.g., preventing contact failure or preventing micro-short-circuit) between the indirect connection portion 130 and the chuck (110 of FIG. 2C) may be improved. In addition, the leaf spring 130L may be efficiently implemented with a highly conductive metal (e.g., copper or aluminum) and may be efficiently implemented with a high current capacity, so that the measuring device (140 of FIG. 2C) may be efficiently configured to output a large current to the indirect connection portion 130.

For example, the jig 130C may be implemented as a connector connected to a power cable, and the power cable may be electrically connected between the jig 130C and the measuring device (140 of FIG. 2C). For example, the position of the jig 130C and/or the support portion 130S may be controlled by the controller (CTL of FIG. 2B), and force for moving may be received from the controller (CTL of FIG. 2B). For example, the support member 130S may support the leaf spring 130L, include a durable material (e.g., a metal material or a non-metal material), and have a plate shape.

Referring to FIG. 3, the direct connection member 120 may further include a connecting member 122 having a through-hole, through which the plurality of wire probes 121 pass, and being fixed to the plurality of wire probes 121 through the through-hole. Accordingly, the positions of the plurality of wire probes 121 may be stably fixed even when the plurality of wire probes 121 are bent. That is, the connecting member 122 may stably support the bending for shock alleviation of the plurality of wire probes 121.

For example, the connecting member 122 may include a lower fixing member 122L having a through-hole, through which a plurality of wire probes 121 pass, and being fixed to a lower portion of the plurality of wire probes 121 through the through-hole, an upper fixing member 122U having a through-hole, through which a plurality of wire probes 121 pass, and being fixed to an upper portion of the plurality of wire probes 121 through the through-hole, and a support member 122S supporting between the lower fixing member 122L and the upper fixing member 122U.

For example, the position of the connecting member 122 may be controlled by the controller (CTL of FIG. 2B) and force for moving may be received from the controller (CTL of FIG. 2B). For example, the support member 122S may be disposed to surround the plurality of wire probes 121. For example, each of the lower fixing member 122L, the upper fixing member 122U, and the support member 122S may include a durable material (e.g., a metal material or a non-metallic material) and may have a plate shape. The upper fixing member 122U may be connected to a jig 122C, the jig 122C may be implemented as a connector connected to a power cable, and the power cable may be electrically connected between the jig 130C and the measuring device (140 of FIG. 2C).

Referring to FIG. 3, depending on the design, each of the plurality of wire probes 121 may include a wire body 121S and a contact portion 121C. The contact portion 121C may be connected between the wire body 121S, and the power semiconductor chip (PSC of FIG. 4) and may have a diameter shorter than the diameter of the wire body 121S. Accordingly, the contact portion 121C may be bent more easily than the wire body 121S, and stress concentrated on the contact portion 121C may be efficiently alleviated.

The apparatus and method for testing a power semiconductor chip according to an embodiment of the present disclosure may prevent damage to the power semiconductor chip when forming a path through which a large current for testing the power semiconductor chip flows.

While example embodiments have been illustrated and described above, it will be apparent to those skilled in the art that modifications and variations could be made without departing from the scope of the present disclosure as defined by the appended claims.

1. An apparatus for testing a power semiconductor chip, the apparatus comprising:
a chuck having a surface configured so that a power semiconductor chip is positioned on the surface of the chuck;
a direct connection portion including a plurality of wire probes directly contacting a first surface of the power semiconductor chip; and
an indirect connection portion forming an electrical connection path to a second surface of the power semiconductor chip through the chuck;
wherein each of the plurality of wire probes is configured to be bendable by pressure applied to both ends of each of the plurality of wire probes.

2. The apparatus of claim 1, wherein the indirect connection portion is configured to directly contact a region of a surface of the chuck not overlapping the power semiconductor chip.

3. The apparatus of claim 2, wherein the indirect connection portion includes a leaf spring.

4. The apparatus of claim 1, further comprising a measuring device configured to output current to the indirect connection portion and to measure an electrical parameter through the direct connection portion.

5. The apparatus of claim 1, wherein the chuck has a vacuum suction hole configured to suck the power semiconductor chip.

6. The apparatus of claim 1, wherein each of the plurality of wire probes includes a wire body and a contact portion, each of the contact portions being connected between the wire body and the power semiconductor chip and having a diameter shorter than a diameter of the wire body.

7. The apparatus of claim 1, wherein a total current capacity of the plurality of wire probes exceeds 100 A.

8. The apparatus of claim 7, wherein a current capacity of each of the plurality of wire probes is less than 10 A.

9. The apparatus of claim 1, wherein the direct connection portion further includes a connecting member having a through-hole, through which the plurality of wire probes pass, and being fixed to the plurality of wire probes through the through-hole.

10. The apparatus of claim 9, wherein
the connecting member includes:
a lower fixing member having a through-hole, through which the plurality of wire probes pass, and being fixed to a lower portion of the plurality of wire probes through the through-hole of the lower fixing member;
an upper fixing member having a through-hole, through which the plurality of wire probes pass and being fixed to an upper portion of the plurality of wire probes through the through-hole of the upper fixing member; and
a support member positioned between the lower fixing member and the upper fixing member.

11. The apparatus of claim 1, wherein the power semiconductor chip is a single power semiconductor chip, and is one of a plurality of power semiconductor chips divided from a wafer.

12. The apparatus of claim 11, wherein a total arrangement range of the plurality of wire probes is less than or equal to an area of one surface of the single power semiconductor chip.

13. A method for testing a power semiconductor chip, the method comprising:
placing a power semiconductor chip on a vacuum suction hole of one surface of a chuck;
bringing a plurality of wire probes electrically connected to a measuring device into contact with the power semiconductor chip and connecting an indirect connection portion electrically connected to the measuring device to the chuck to form a current path; and
outputting by the measuring device, current to the indirect connection portion, and measuring an electrical parameter through the plurality of wire probes.

14. The method of claim 13, wherein the indirect connection portion includes a leaf spring.

15. The method of claim 13, wherein, when forming the current path, the indirect connection portion is disposed in a region of one surface of the chuck not overlapping the power semiconductor chip.

16. The method of claim 15, wherein a total current flowing through the plurality of wire probes exceeds 100 A, and current flowing through each of the plurality of wire probes is less than 10 A.

17. The method of claim 13, wherein the power semiconductor chip disposed on the vacuum suction hole of the chuck by the placing operation is a single power semiconductor chip, and is one of a plurality of power semiconductor chips divided from a wafer, and a total arrangement range of the plurality of wire probes directly contacting the single power semiconductor chip by the forming operation is less than or equal to an area of one surface of the single power semiconductor chip.
